(19) United States
(12) Patent Application Publication
(10) Pub. No.: US 2015/0271954 A1
(43) Pub. Date: Sep. 24, 2015

(54) HEAT DISSIPATION DEVICE

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: ZHI-YONG GAO, Wuhan (CN); SAN-YONG YANG, Wuhan (CN)

(21) Appl. No.: 14/584,782

(22) Filed: Dec. 29, 2014

(30) Foreign Application Priority Data
Mar. 18, 2014 (CN) 201410099756.6

(51) Int. Cl. H05K 7/20

(52) U.S. Cl. CPC H05K 7/20263

(57) ABSTRACT

A heat dissipation device includes a fan, a heat dissipating member, a water pipe, and a water drawing device. The heat dissipating member includes a plurality of fins which are hollowed to permit the passage of water. The water pipe includes an inlet pipe and an outlet pipe. The water drawing device is configured to pump water to the inlet pipe, and draw the water back from the outlet pipe through the plurality of fins to cool the plurality of fins.

### CROSS-REFERENCE TO RELATED APPLICATIONS

This application claims priority to Chinese Patent Application No. 201410099756.6 filed on Mar. 18, 2014, the contents of which are incorporated by reference herein.

### FIELD

The subject matter herein generally relates to temperature control.

### BACKGROUND

When electronic devices are in a working state, the circuit and the microprocessor can generate heat. If the heat is not reduced in time, the electronic devices will be damaged.

### BRIEF DESCRIPTION OF THE DRAWINGS

Implementations of the present technology will now be described, by way of example only, with reference to the attached figures.

FIG. 1 is an exploded, isometric view of one embodiment of a heat dissipation device.

FIG. 2 is similar to FIG. 1, but viewed from another angle.

FIG. 3 is an isometric, cross-sectional view of the heat dissipation device of FIG. 1.

FIG. 4 is an isometric, internal structure view of the heat dissipation device of FIG. 1.

FIG. 5 is an assembled view of the heat dissipation device of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure is described in relation to a heat dissipation device.

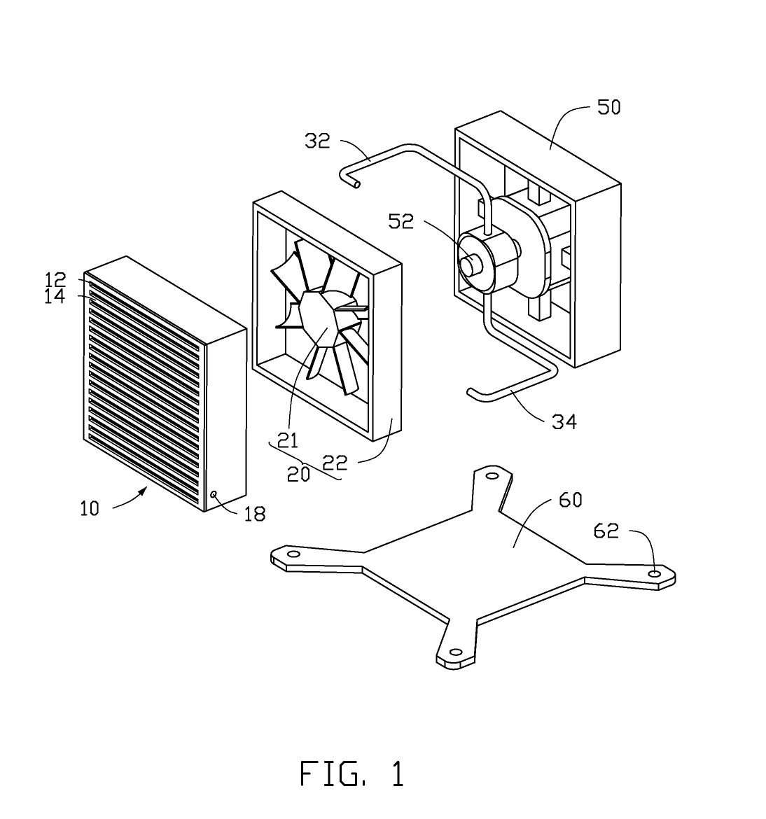

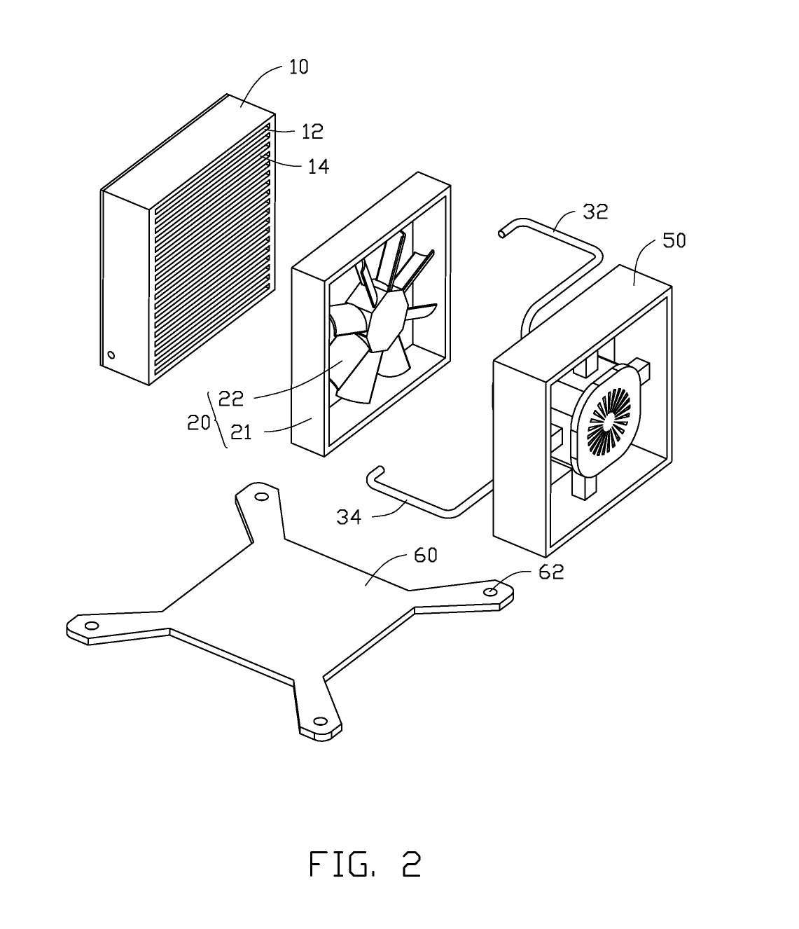

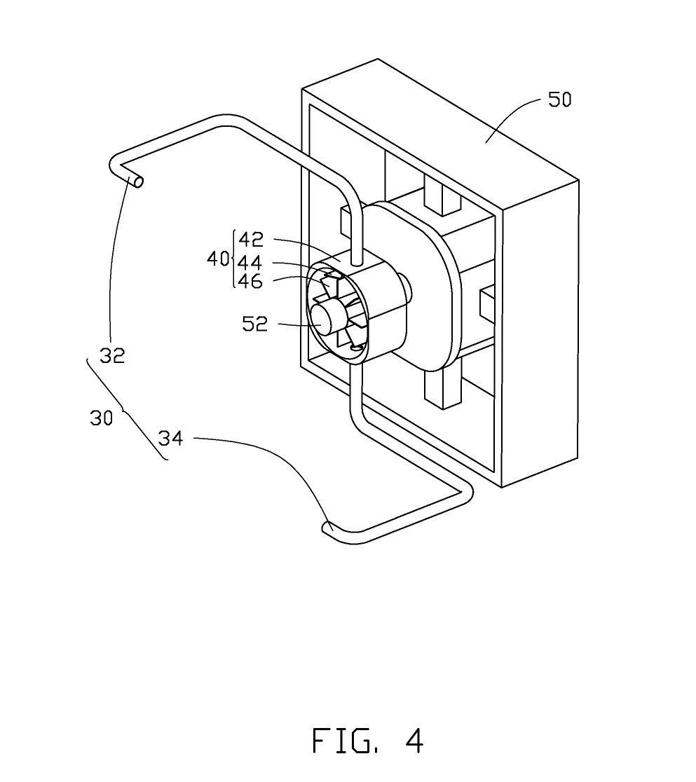

FIGS. 1-4 illustrate one embodiment of a heat dissipation device. The heat dissipation device includes a heat dissipating member 10, a fan 20, a water pipe 30, a water drawing device 40, a motor 50, and a heat exchanging plate 60.

The heat dissipating member 10 defines a plurality of vents 12, a water inlet 16, and a water outlet 18. The heat dissipating member 10 includes a plurality of fins 14. The fins of the plurality of fins 14 are substantially parallel to each other. The vents of the plurality of vents 12 are spaced from each other. Each fin 14 is located between two vents 12. Each fin 14 defines a guiding channel 142. The guiding channels of the plurality of guiding channels 142 connect to each other. The water inlet 16 and the water outlet 18 connect to the guiding channels 142.

The fan 20 includes a body 21 and a frame 22. The water pipe 30 includes an inlet pipe 32 and an outlet pipe 34. The water drawing device 40 includes a shell 42, a guiding piece 44, and a plurality of blades 46. The guiding piece 44 is engaged with the shell 42. The motor 50 includes a shaft 52. The heat exchanging plate 60 defines a plurality of holes 62.

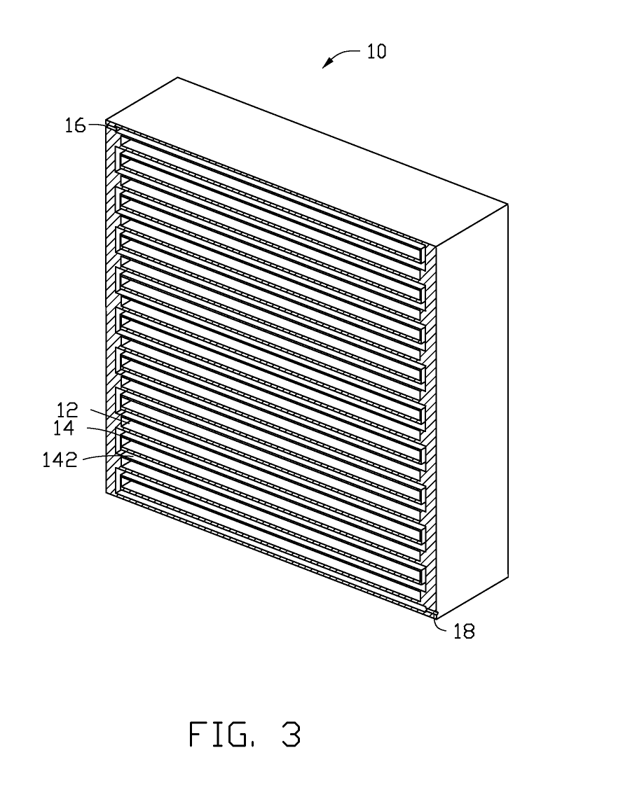

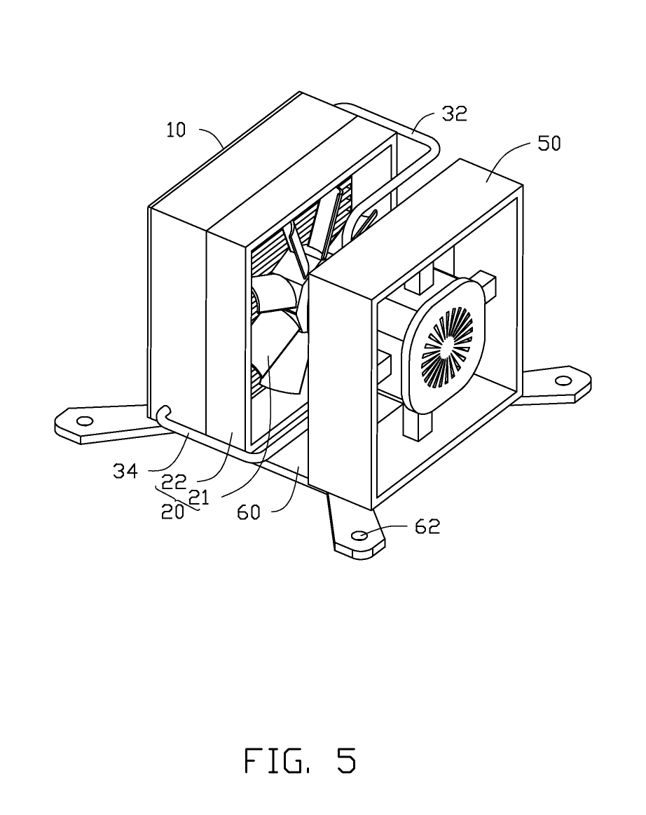

FIG. 3-FIG. 5 show views of the assembled heat dissipation device. The plurality of blades 46 is engaged with the shaft 52. The plurality of blades 46 and the shaft 52 are located in the shell 42. One end of the inlet pipe 32 connects to the water inlet 16 and an opposite end of the inlet pipe 32 connects to the shell 42. One end of the outlet pipe 34 connects to the water outlet 18 and an opposite end of the outlet pipe 34 connects to the shell 42. The shell 42, the inlet pipe 32, the outlet pipe 34, and the guiding channels 142 cooperatively define a loop. The guiding piece 44 is located on a joint of the inlet pipe 32 and the shell 42. The body 21 is mounted on an end of the shaft 52. The frame 22 of the fan 20 is fixed to the heat dissipating member 10. The fan 20 is located between the heat dissipating member 10 and the water drawing device 40. The heat dissipating member 10, the fan 20, and the motor 50 are secured to the heat exchanging plate 60. The heat exchanging plate 60 is secured to an electronic device by the plurality of holes 62.

In use, the shaft 52 is forced to rotate by the motor 50. The motor 50 rotates the plurality of blades 46. The fan 20 generates an airflow through the plurality of vents 12 of the heat dissipating member 10, to cool the plurality of fins 14. The direction of the airflow is substantially perpendicular to an extending direction of each fin 14. The plurality of blades 46 pumps the water from the outlet pipe 34 and draws the water back to the inlet pipe 32. The guiding piece 44 guides the water flow into the inlet pipe 32. The water in the inlet pipe 32 flows through the guiding channel 142 to cool the plurality of fins 14. The water in the guiding channel 142 flows through the outlet pipe 34 and back to the water drawing device 40.

The embodiments shown and described above are only examples. Many details are often found in the art such as the other features of a heat dissipation device. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A heat dissipation device comprising:
a heat dissipating member comprising a plurality of fins;
a water pipe comprising an inlet pipe and an outlet pipe; and
a water drawing device;
wherein the water pipe is engaged with the heat dissipating member and the water drawing device, the water drawing device is configured to pump water to the inlet pipe, and draw the water back from the outlet pipe through the plurality of fins to cool the plurality of fins.

2. The heat dissipation device of claim 1, wherein the heat dissipating member defines a plurality of vents, the plurality of vents is spaced from each other, and each fin is located between the two of the plurality of vents.

3. The heat dissipation device of claim 2, further comprising a fan, wherein the fan generates an airflow extending through the plurality of vents to cool the plurality of fins, the direction of the airflow is substantially perpendicular to an extending direction of each fin.

4. The heat dissipation device of claim 3, wherein the fan is located between the heat dissipating member and the water drawing device.

5. The heat dissipation device of claim 1, wherein the plurality of fins is substantially parallel to each other.

6. The heat dissipation device of claim 1, wherein each fin defines a guiding channel, and the plurality of guiding channels connects to each other.

7. The heat dissipation device of claim 6, wherein one end of the inlet pipe connects to one of the plurality of guiding channels and the other end of the inlet pipe connects to the water drawing device, and one end of the outlet pipe connects to the one of the plurality of guiding channels and the other end connects to the water drawing device.

8. The heat dissipation device of claim 1, further comprising a motor, the motor comprising a shaft, wherein the water drawing device comprises a plurality of blades, and the plurality of blades is engaged with the shaft.

9. The heat dissipation device of claim 8, wherein the fan comprises a body, and the body is mounted to an end of the shaft.

10. The heat dissipation device of claim 1, wherein the water drawing device comprises a guiding piece and a shell, and the guiding piece is located on a joint of the inlet pipe and the shell.

11. A heat dissipation device comprising:
a fan; and
a heat dissipating member comprising a plurality of fins and defining a plurality of vents, each fin defining a guiding channel, and the plurality of guiding channels connects to each other;
wherein the fan is configured to locate on one side of the heat dissipating member, the fan generates an airflow extending through the plurality of vents to cool the plurality of fins, a water flows through the plurality of guiding channels to cool the plurality of fins.

12. The heat dissipation device of claim 11, wherein the plurality of vents is spaced from each other, and each fin is located between the two of the plurality of vents.

13. The heat dissipation device of claim 11, wherein the plurality of fins is substantially parallel to each other.

14. The heat dissipation device of claim 11, wherein the direction of the airflow is substantially perpendicular to an extending direction of each fin.

15. The heat dissipation device of claim 11, further comprising a water pipe and a water drawing device, the water pipe comprising a inlet pipe and a outlet pipe, wherein one end of the inlet pipe connects to the one of the plurality of guiding channels and the other end connects to the water drawing device, and one end of the outlet pipe connects to the one of the plurality of guiding channels and the other end connects to the water drawing device.

16. The heat dissipation device of claim 15, wherein the fan is located between the heat dissipating member and the water drawing device.

17. The heat dissipation device of claim 15, further comprising a motor, the motor comprising a shaft, wherein the water drawing device comprises a plurality of blades, and the plurality of blades is engaged with the shaft.

18. The heat dissipation device of claim 17, wherein the fan comprises a body, and the body is mounted on an end of the shaft.

19. The heat dissipation device of claim 15, wherein the water drawing device comprises a guiding piece and a shell, and the guiding piece is located on a joint of the inlet pipe and the shell.
